(19) United States
(12) Patent Application Publication
(10) Pub. No.: US 2026/0173336 A1
(43) Pub. Date: Jun. 18, 2026

(54) ACOUSTIC DEFLECTOR SHIELD

(71) Applicant: SAGEMCOM BROADBAND SAS, BOIS-COLOMBES (FR)

(72) Inventors: Charles-Efflam MARTIN DE MONTAUDRY, BOIS-COLOMBES (FR); Gilles BOURGOIN, BOIS-COLOMBES (FR)

(21) Appl. No.: 19/421,723

(22) Filed: Dec. 16, 2025

(30) Foreign Application Priority Data
Dec. 16, 2024 (FR) FR2414257

(51) Int. Cl. H05K 9/00; H04R 1/02

(52) U.S. Cl. CPC H05K 9/0024; H04R 1/02

(57) ABSTRACT

Audio equipment including a printed circuit on which at least one electronic component is mounted; a speaker; a shielding cover arranged to protect the electronic component. The shielding cover comprising an external face positioned facing the diaphragm of the speaker. The external face includes at least one curved surface that extends from a central part of the external face towards a contour of the external face, the shielding cover thus being arranged to diffract acoustic waves produced by the diaphragm of the speaker in operation so as to reduce undesirable vibrations of the printed circuit and of the shielding cover.

The invention relates to the field of audio equipment integrating both an electronic component or components requiring electromagnetic shielding, and a speaker or speakers.

### BACKGROUND OF THE INVENTION

Some equipment integrate both electronic components for implementing complex functions, and an audio device comprising one or more speakers.

This is the case, for example, of certain set-top boxes (or STBs) which integrate speakers and which, in addition to performing their “conventional” functions (acquisition of an audio-video stream, decoding, stream broadcasting, etc.), at least partially restore the audio stream.

Such an “advanced” set-top box comprises electronic processing components which must be protected against electromagnetic disturbances and thus require electromagnetic shielding. However, this type of equipment is relatively compact, and integrating electronic components, shielding devices and speakers is relatively complicated.

Such a set-top box 1 is shown in FIGS. 1 to 4.

The external shell of the set-top box 1 comprises an upper cover 2 defining an upper face of the set-top box 1. The set-top box 1 comprises an electronic board 3, in this case, the motherboard, that comprises a printed circuit 4 on which electronic components are mounted. The printed circuit 4 is attached to the upper cover 2 by screw connections at its four corners. Among the electronic components, there are electronic components 5 which are protected by an electromagnetic shielding device 6.

The shielding device 6 is formed, for example, by a shielding belt 7, mounted on the electronic board 3, and by a shielding cover 8 force-fitted around the belt 7. For example, these shielding elements may be made of sheet metal folded over the entire periphery, embossed and cut out, 0.2 mm thick.

The set-top box 1 also comprises a speaker 10 integrated in an acoustic box 11 itself integrated in the set-top box 1. In this case, this speaker 10 is a woofer that, because of the very limited space available, is located in the vicinity of the shielding device 6. The shielding cover 8 comprises a planar-shaped external face located opposite and very close to the diaphragm 12 of the speaker 10, and therefore parallel to the acoustic wave generated by the speaker 10. The air then escapes mainly through the sides and the back of the set-top box 1, as indicated by the arrows in FIGS. 1 and 2.

This method raises the following problems.

The energy generated by the movement of the diaphragm 12 of the speaker 10 produces undesirable vibrations of the sub-assembly comprising the electronic board 3 and the shielding cover 8. Furthermore, since the shielding cover 8 is located just above the speaker 10, the speaker may also vibrate independently against the shielding belt 7.

Furthermore, the mechanical architecture of the set-top box 1 generates the presence of a cavity around the speaker 10 with many parallel planes between the acoustic box 11 and the upper cover 2. This particular configuration thus generates acoustic resonance and creates stationary waves between the speaker 10 and the electronic board 3.

This phenomenon can be seen clearly in the graph in FIG. 5. The frequency response C1 of the speaker 10, while the latter is integrated in its acoustic box 11 and the box 11 is assembled with the upper cover 2, comprises a peak 14 registered at about 1 kHz. On the other hand, it can be seen that the frequency response C2 of the speaker 10 does not comprise this peak at 1 kHz when the box 11 is not assembled with the upper cover 2.

The configuration of the speaker 10 and of the shielding cover 8 that has just been described may therefore lead to sound diffusion that is not homogeneous and that may be contaminated by distortions (Total Harmonic Distortion) and vibrations (Rub & Buzz).

### AIM

The aim of the invention is to limit unwanted vibratory phenomena in audio equipment integrating at least one speaker and at least one electronic component protected by a shielding cover.

### SUMMARY

In order to achieve this aim, audio equipment is proposed, comprising:
a printed circuit on which at least one electronic component is mounted;
a speaker comprising a diaphragm;
a shielding cover arranged to protect the at least one electronic component from electromagnetic disruptions, the shielding cover comprising an external face positioned facing the diaphragm of the speaker;
the external face comprising at least one curved surface that extends from a central portion of the external face towards a contour of the external face, the shielding cover thus being arranged to diffract acoustic waves produced by the diaphragm of the speaker in operation so as to reduce undesirable vibrations of the printed circuit and the shielding cover.

The particular shape of the shielding cover makes it possible to diffuse the incident acoustic energy produced by the movement of the diaphragm of the speaker, and thus to dissipate more effectively the air flow generated by the speaker. The shielding cover thus performs a dual function. On the one hand, it makes it possible to protect the electronic components from electromagnetic disruptions, and on the other hand, it makes it possible to limit or even eliminate unwanted vibratory phenomena, and thus to improve the sound rendering of the audio equipment. The invention is particularly advantageous in compact audio equipment wherein the speaker is positioned very close to the shielding cover.

In addition, an audio equipment such as described above is proposed, wherein a central axis of the shielding cover, passing through a centre of the external face, is combined with a central axis of the speaker.

In addition, an audio equipment such as described above is proposed, wherein a free space that extends between, on the one hand, the diaphragm and a core cover of the speaker, and, on the other hand, the shielding cover, has a h substantially constant height.

In addition, an audio equipment such as described above is proposed, wherein the diaphragm is a circular membrane and wherein the height h is such that:

$$h = \frac{D}{4} ,$$

where D is a diameter of the diaphragm.

Also proposed is a piece of audio equipment audio as described above, wherein the external face of the shielding cover comprises:
a frustoconical surface, comprising a concavity that extends inside of the frustoconical surface;
a bead that extends at least over a certain length of the contour of the external face;
and wherein the diaphragm of the speaker extends facing the frustoconical surface, a core cover of the speaker extends facing the concavity, and a suspension of the speaker extends at least partially in a channel defined between the bead and the frustoconical surface.

In addition, an audio equipment such as described above is proposed, wherein the bead extends over only a portion of the length of the contour of the external face, such that said channel comprises two ends and allows an air flow moved by the diaphragm of the speaker to flow via these two ends.

In addition, audio equipment such as described above is proposed, wherein the external face of the shielding cover has, when viewed in cross-section along a plane passing through the central axis of the shielding cover, a parabolic shape at the bead.

In addition, audio equipment such as described above is proposed, wherein the shielding cover comprises, in terms of at least one end of the channel, an extension that extends the bead and that at least partially covers another component mounted on the printed circuit.

In addition, audio equipment such as described above is proposed, wherein the shielding cover is attached to a shielding belt mounted on the printed circuit and surrounding the at least one electronic component, the shielding cover having an internal face wherein an internal cavity is formed, the shielding cover extending on either side of the shielding belt that is positioned in the internal cavity.

Also, an audio equipment as previously described is provided, the audio equipment being a set-top box.

The invention will be best understood, in the light of the following description of particular, non-limiting embodiments of the invention.

### BRIEF DESCRIPTION OF THE DRAWINGS

Reference will be made to the accompanying drawings, among which:

FIG. 1 shows a perspective and top view of a sub-assembly of a set-top box of the prior art;

FIG. 2 shows a perspective, side and cross-sectional view along a transversal plane, of the sub-assembly of the set-top box;

FIG. 3 shows a bottom view of the upper cover and the electronic board, while the shielding cover is not mounted on the shielding belt;

FIG. 4 is a view similar to FIG. 3, while the cover is also mounted on the shielding belt;

FIG. 5 is a graph showing curves of the frequency response of the speaker in the acoustic box, assembled and unassembled with the upper cover;

FIG. 6 shows a diagrammatic and cross-sectional view of a sub-assembly of a set-top box comprising an upper cover, an electronic board, a shielding cover according to a first embodiment, and an acoustic box integrating a speaker;

FIG. 7 is a figure similar to FIG. 4, showing a shielding cover according to a second embodiment;

FIG. 8 is a figure similar to FIG. 7, but with a side view;

FIG. 9 is a perspective and cross-sectional view along a transversal plane of the “returned” sub-assembly of the set-top box;

FIG. 10 shows a Helmholtz resonator;

FIG. 11 is a graph showing movement curves of the sub-assembly comprising the upper cover and the electronic board, with a conventional shielding cover and with the shielding cover according to the second embodiment;

FIG. 12 is a graph showing curves of the frequency response at a distance of 10 cm behind the acoustic box, the latter being integrated with a conventional shielding cover and with the shielding cover according to the second embodiment.

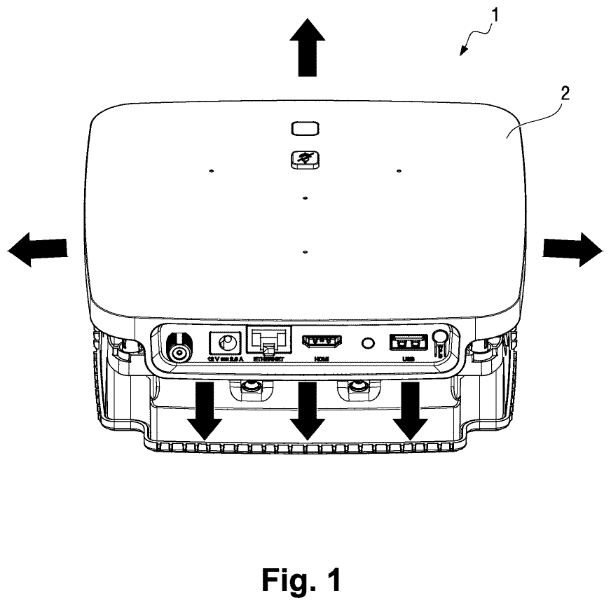

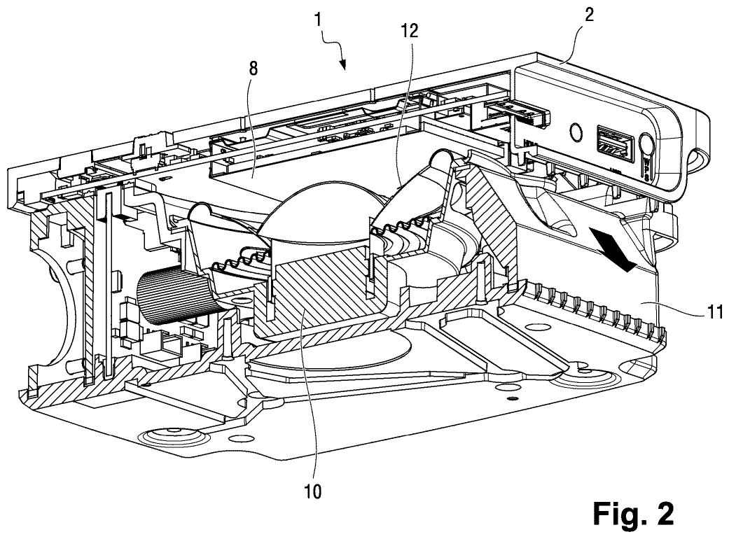

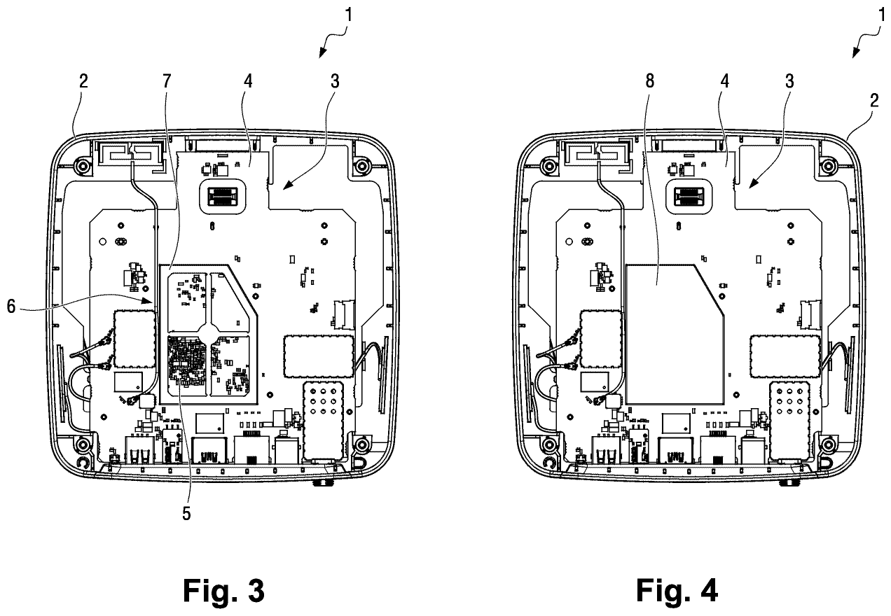

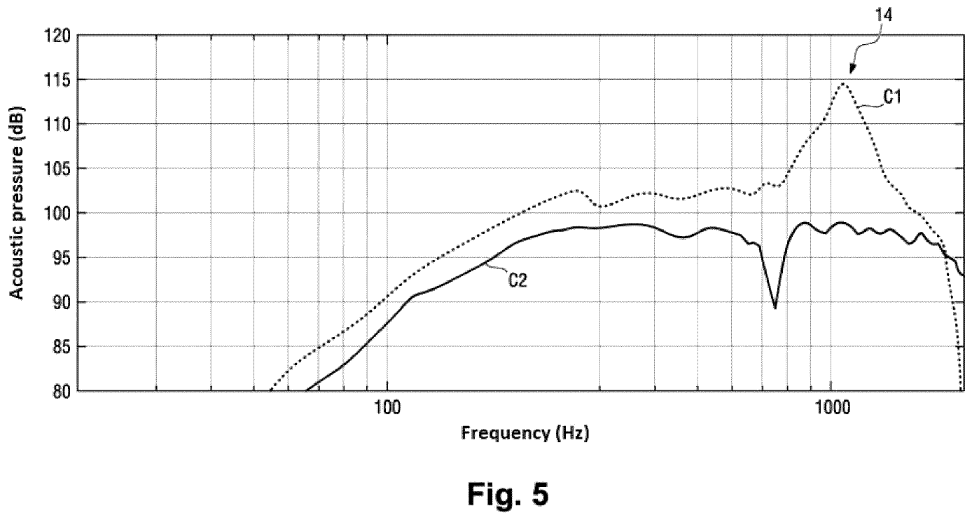

### DETAILED DESCRIPTION

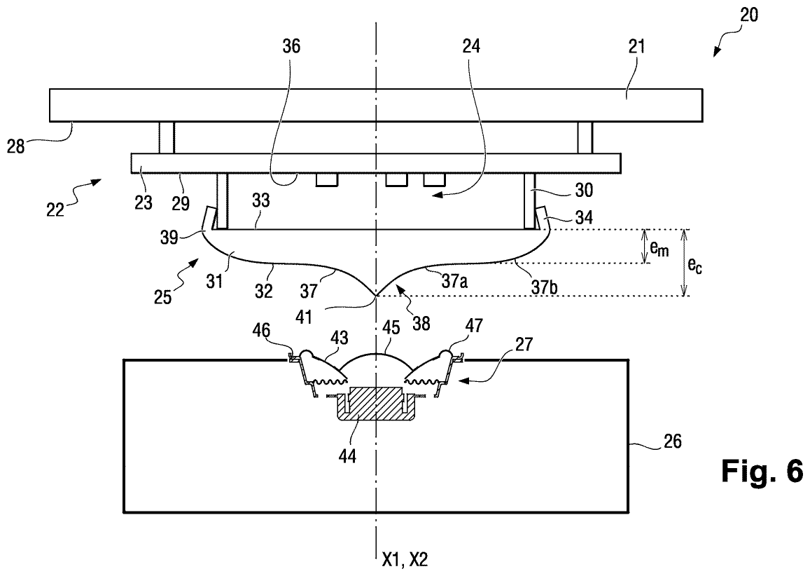

With reference to FIG. 6, the set-top box 20 comprises an upper cover 21, an electronic board 22 comprising a printed circuit 23 and at least one electronic component 24 mounted on the printed circuit 23, a shielding device 25, and an acoustic box 26 integrating a speaker 27.

The printed circuit 23 is attached to an internal face 28 of the upper cover 21 by screw connections, and extends parallel to it.

The electronic component 24 is mounted on an internal face 29 of the printed circuit 23.

The shielding device 25 serves to protect the electronic component 24 from electromagnetic disturbances generated by other components of the set-top box 20.

In a first embodiment, the shielding device 25 comprises a shielding belt 30 and a shielding cover 31. The shielding belt 30 is attached to the printed circuit 23 and extends around the electronic component 24. The shielding belt 30 is in direct contact with a ground plane of the electronic board 22 over its entire circumference.

The shielding cover 31 is formed by a single piece of bent sheet metal. The shielding cover 31 comprises an external face 32, an internal face 33, and a peripheral portion 34.

The external face 32 and the internal face 33 are surfaces of revolution about a central axis X1 of the shielding cover 31. The peripheral portion 34, that is cylindrically-shaped and has the central axis X1 as its axis, extends from the contour of the internal face 33 of the shielding cover 31.

The peripheral portion 34 is force-fitted around the shielding belt 30 to attach the shielding cover 31 to the shielding belt 30 and thus to the electronic board 22. The peripheral portion 34 is then positioned against the shielding belt 30 and outside of the surface 36 of the electronic board 22 delimited by the belt 30, wherein the component 24 is located.

The external face 32 of the shielding cover 31 comprises at least one curved surface 37 that extends from a central portion 38 of the external face 32 towards the contour 39 of the external face 32, the shielding cover 31 thus being arranged to diffract acoustic waves produced by the speaker 27 in operation so as to reduce undesirable vibrations of the printed circuit 23 and the shielding cover 31.

In this case, the central portion 38 of the external face 32 forms a peak whose apex is at the centre 41 of the external face 32. The external face 32 comprises a first curved surface 37a and a second curved surface 37b which extend successively along a radial direction from the peak towards the contour 39 of the external face 32. The first curved surface 37a and the second curved surface 37b are also surfaces of revolution about the central axis X1 of the shielding cover 31.

The first curved surface 37a is a concave surface and the second curved surface 37b is a convex surface.

The speaker 27 itself conventionally comprises a diaphragm 43, a core 44, a core cover 45, a frame 46, and a suspension 47 that makes it possible to attach the diaphragm 43 to the frame 46. The speaker 27 is a Woofer-type speaker. This is a speaker that reproduces low frequencies, for example, of between 100 Hz and 2 kHz. In this case, the speaker 27 has a cut-off frequency of 300 Hz.

The diaphragm 43 is, in this case, a circular membrane.

In this case, the central axis X1 of the shielding cover 31, passing through the centre 41 of the external face 32, and the central axis X2 of the speaker 27 are combined. The term “combined” is used to mean that they are actually combined, or that the distance between them is very short.

Thus, advantageously:

$$d < \frac{D}{20} ,$$

where d is the distance between the two central axes X1, X2 and D is the diameter of the diaphragm 43.

The internal face 33 of the shielding cover 31 is a planar surface. The shielding cover 31 is thickened, i.e., the thickness of the e shielding cover 31, that is therefore the dimension along an axis parallel to the axis X1 between the external face 32 and the internal face 33, is greater than that of a conventional sheet metal cover.

In this case, the thickness e_{c} of the cover 31 at the centre 41 of the cover 31 is such that:

$${e}_{c} > 2 \times {e}_{m} ,$$

where eₘ is the minimum thickness of the cover 31.

This particular shape of the shielding cover 31, as well as the centred position of the shielding cover 31 relative to the speaker 27, have the effect of promoting the diffraction and then the diffusion of the incident acoustic wave, and thus of reducing the vibrational energy transmitted to the electronic board 22. This shape and position also make it possible to limit or even eliminate the formation of stationary waves by avoiding parallel planes. Furthermore, thickening the shielding cover 31 makes it possible to stiffen the shielding cover 31 in order to prevent any risk of vibrations against the shielding belt 30.

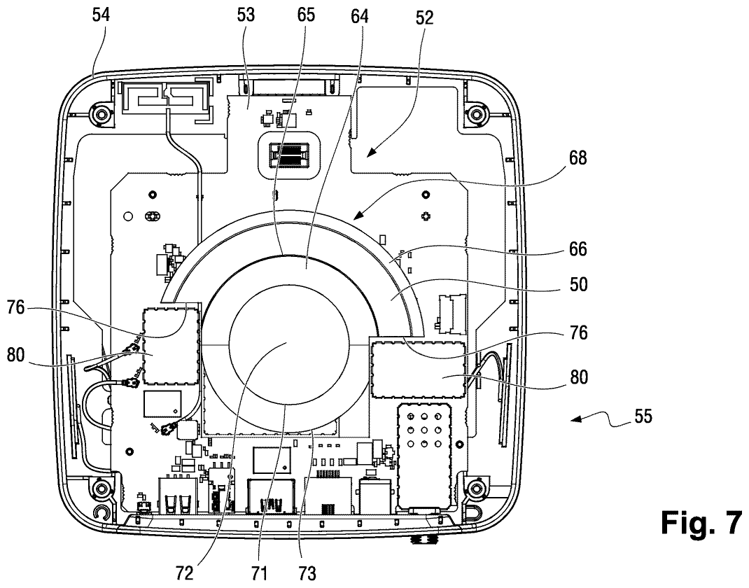

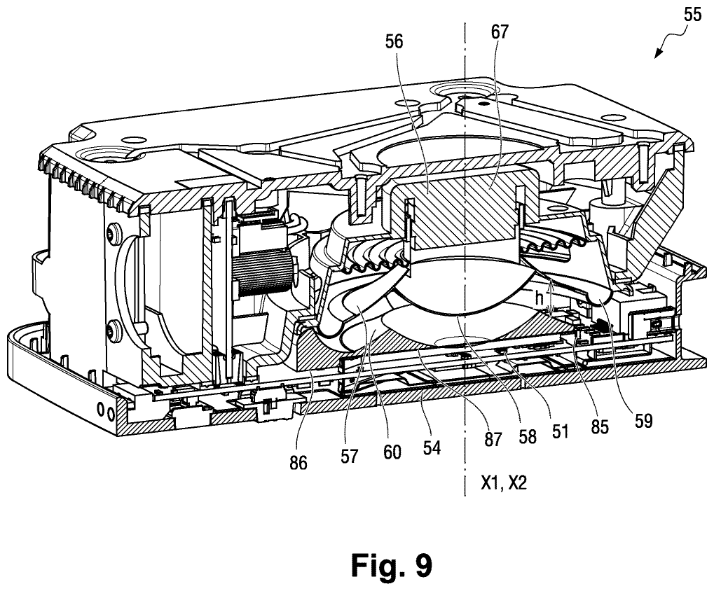

With reference to FIGS. 7 to 9, there follows a description of a shielding cover 50 according to a second embodiment of the invention.

Once again, the purpose of the shielding cover 50 is to protect one or more electronic components 51 of an electronic board 52 whose printed circuit 53 is attached to the upper cover 54 of the set-top box 55.

This time, the shape of the shielding cover 50 is different and adapted to a very small available space.

The speaker 56, that is again a woofer, comprises a diaphragm 57, a core 67, a core cover 58 and a suspension 59.

A free space 60, that extends between, on the one hand, the diaphragm 57 and the core cover 58, and, on the other hand, the shielding cover 50, has a h substantially constant height. In this example, this height h is defined according to a dimension parallel to the central axis X1 of the shielding cover 50 and to the central axis X2 of the speaker 56, which are combined.

In this case, the term “substantially constant” is used to mean that this height h is constant at ±10%.

This free space 60 forms an air passage.

The profile of the external surface of the speaker 56 facing this passage 60 is identical to the profile of the external face 61 of the shielding cover 50 facing said passage 60.

The shape of the cover 50 therefore follows the profile of the diaphragm 57 of the speaker 56, that makes it possible to maximise the non-planar surface facing the speaker 56, while taking into account the maximum clearance of its diaphragm 57.

The external face 61 of the shielding cover 50 comprises:
a frustoconical surface 64 and a concavity 65 that extends inside of the frustoconical surface 64;
a bead 66 that extends at least over a certain length of the contour 68 of the external face 61.

The frustoconical surface 64 and the concavity 65 are surfaces of revolution about the central axis X1 of the shielding cover 50.

The diaphragm 57 of the speaker 56 extends facing the frustoconical surface 64, a core cover 58 of the speaker 56 extends facing the concavity 65, and a suspension 59 of the speaker 56 extends at least partially in a channel 70 defined between the bead 66 and the frustoconical surface 64.

The frustoconical surface 64 has a first end 71 (that delimits the concavity 65), in this case, a circular end, located on the side of the centre 72 of the external face 61, and a second end 73, also circular, located on the side of the contour 68 of the external face 61. The diameter of the second end 73 is greater than that of the first end 71, and the frustoconical surface 64 thus flares from its first end 71, forming a slope that extends to the second end 73 and to the bottom of the bead 66. The frustoconical surface 64 has a shape that is substantially complementary to that of the diaphragm 57 of the speaker 56.

The concavity 65 forms a curved surface that extends from a central portion 63 of the external face 61 (in this case, from the centre 72 of the external face 61) to the contour 68 of the external face 61. The centre 72 of the external face 61, through which the axis X1 passes, is also the deepest point of the concavity 65.

The concavity 65, in this case, has a parabolic or circular profile and has a shape substantially complementary to that of the core cover 58 of the speaker 56.

The external face 61 of the cover 50, when viewed in cross-section along a plane passing through the central axis X1 of the cover, has a parabolic shape at the bead 66.

Thus, when the set-top box 55 is assembled, the diaphragm 57 extends facing the frustoconical surface 64 and parallel to it, and the core cover 58 extends facing the concavity 65. When the speaker 56 is operating, the diaphragm 57 vibrates and moves, such that the diaphragm 57 and the core cover 58 move towards and away from the external face 61 of the shielding cover 50. The core cover 58 partially penetrates into the concavity 65. The frustoconical surface 64 and the concavity 65 are dimensioned such that the diaphragm 57 and the core cover 58 do not come into contact with the shielding cover 50.

The shape of the shielding cover 50 thus makes it possible to optimise the integration of the speaker 56 and the shielding cover 50, that is extremely advantageous when the very small size does not make it possible to integrate a shielding cover such as the cover 8 according to the first embodiment.

Movement of the diaphragm 57 generates an air flow.

Advantageously, to avoid acoustic disturbances and over-pressures in front of the speaker 56, the flow speed of the air at the outlet of the set-top box 55 must be as close as possible to the movement speed of the diaphragm 57 of the speaker 56. To do so, the multiplication of the height h of the free space 60 above the diaphragm 57 by its perimeter P must be equal to its surface S:

$$h * P = S ,$$

or, in the particular case of a circular diaphragm with a diameter of D

$$h = \frac{D}{4} .$$

It can be seen that the bead 66 extends over only a portion of the length of the contour 68 of the external face 61 of the shielding cover 50, such that the channel 70 comprises two ends 76 and forms an air evacuation channel having said ends 76 as outlets, that allows an air flow 77 moved by the diaphragm 57 of the speaker 56 to flow via these two ends. The air flow is therefore performed in directions parallel to tangents, at the ends 76, to the circle formed by the second end 73 of the frustoconical surface 64.

The air evacuation channel 70 makes it possible to evacuate the air laterally towards the outside of the set-top box 55, in this case, via orifices provided for this purpose in a lower portion of the upper cover 54 that forms an upper portion of the rear face 79 of the set-top box 55.

In this case, it can be seen that two other shielding devices are mounted on the printed circuit 53, with “conventional” shielding covers 80. These shielding covers 80 are positioned such that the air evacuation channel 70 emerges, at each of its ends 76, on one of the shielding covers 80.

It must be noted that the bead 66 may be extended so as to extend over the shielding covers 80, thereby making it possible to obtain a surface without or with little discontinuity and thus to promote the air flow.

The shielding cover 50 may therefore comprise, at least at one end of the channel 70, an extension 81 that extends the bead 66 and that covers, at least partially, another component mounted on the printed circuit 53.

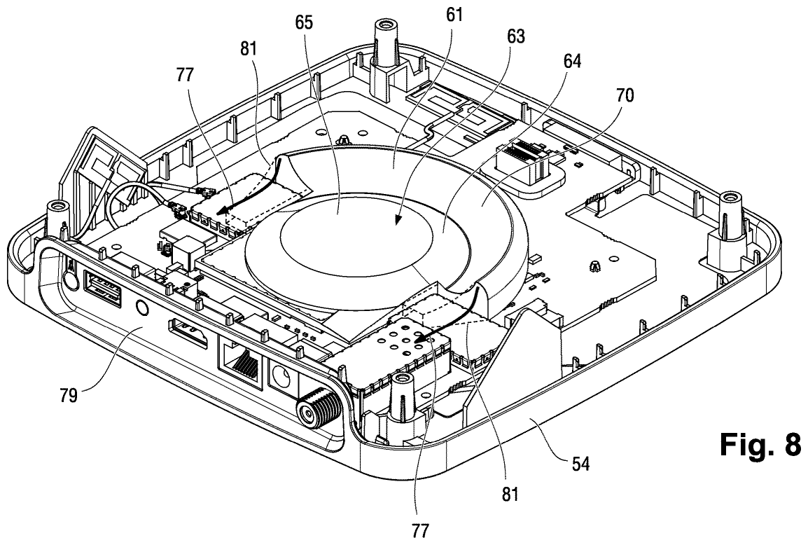

The shielding cover 50 may comprise two extensions 81, i.e., an extension 81 at each end of the channel 70. These are represented schematically, with dotted lines, in FIG. 8.

Each extension 81 then extends along the direction of the air flow 77 and covers, at least partially, one of the shielding covers 80.

Advantageously, each extension 81 of the bead 66 has a parabolic shape when viewed in a plane through which the direction of the air flow 77 at the outlet of the channel 70 passes.

Advantageously, at least one of the ends 76 of the channel 70, or at least one of the extensions 81, emerges on the electronic board 52 at a surface on which is mounted at least one component that requires cooling in order for it to operate. For example, this component may be an audio component that is activated when the speaker 56 is operating. The air flow generated by the speaker 56 and flowing in the channel 70 thus makes it possible to cool this component.

The shielding cover 50 then performs three functions: electromagnetic shielding; acoustic deflector; and cooling.

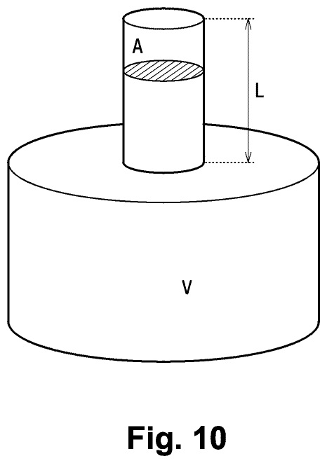

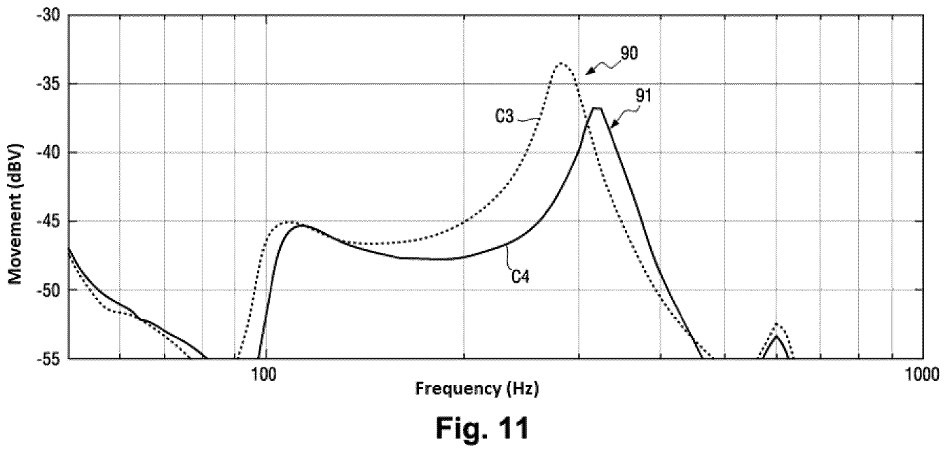

With reference to FIG. 10, an analogy with a simple model makes it possible to assimilate the cavity between the speaker 56 and the acoustic outputs of the set-top box 55 to a Helmholtz resonator:

$${f}_{Helmholtz} = \frac{c}{2 π} \sqrt{\frac{A}{V L}}$$

where c is the speed of sound in air (c=340 m·s⁻¹), A is the section of the neck, L its length, and V the volume of the cavity.

The use of the “deflector” shielding cover 50 makes it possible to reduce the volume V of the cavity. The use of extensions 81 with a parabolic profile makes it possible not to prevent the dimensions of the section from being reduced.

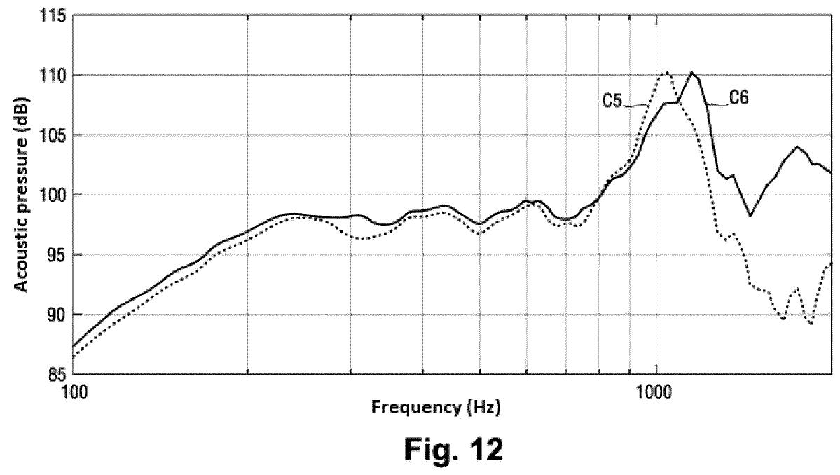

Thus, by reducing the volume V, the deflector shielding cover 50 has the effect of increasing the associated acoustic resonant frequency such that it is outside of the bandwidth of the speaker (e.g., a woofer). This advantage of the deflector shielding cover 50 is described below according to the example in FIG. 12.

It can also be seen that the particular profile of the shielding cover 50 makes it possible to stiffen the shielding cover 50 more effectively by shifting the addition of material, and thus of mass, from the centre of the sheet to distribute it over the periphery of the shielding cover 50 and thus at the bead 66.

In this case, moreover, in order to limit, as much as possible, the presence of parallel planes and to increase the efficiency of sound diffusion and diffraction, the shielding cover 50 extends on either side of the shielding belt 85.

In this case, the following is had:

$$d 1 > 1 , 3. d 2 ,$$

where d1 is the diameter of the shielding cover 50 and d2 is the diameter of the shielding belt 85.

The cover 50 comprises an internal face 86.

An internal cavity 87 is formed in the internal face 86. The internal cavity 87 is positioned at the centre of the internal face 86, and has a cylindrical shape and a diameter substantially equal to (very slightly greater than) that of the shielding belt 85. When the shielding cover 50 is attached to the shielding belt 85, the latter is positioned in the internal cavity 87 and the lateral surface of the internal cavity 87 is applied against the external surface of the shielding belt 85.

In general, the diameter d1 of the shielding cover 50 is determined as a function of the volume available in the internal cavity 87, this volume being defined as a function of the diameter of the internal cavity.

With reference to FIG. 11, measurements have been made of the movement of a sub-assembly comprising the upper cover 50 and the electronic board 52, by means of a laser measuring device, when the speaker 56 is in operation.

It can be seen that, with a conventional shielding cover (without deflecting effect), the frequency response C3 comprises a resonance peak 90 corresponding to the maximum movement of the upper cover. With the shielding cover 50, it can be seen that the amplitude of the resonance peak 91 of the frequency response C4 has decreased by 30%, and thus that the maximum movement of the upper cover 54 has also decreased by 30%. It must also be noted that there is an increase in the resonant frequency of the peak by 12%.

Very significant is this increase in the resonant frequency, and therefore in the frequency of the maximum movement measured. Indeed, if it is made higher than the cut-off frequency of the speaker 56 (e.g., 300 Hz in the case of the set-top box 55), it cannot be reached and therefore the set-top box 55 will not undergo the effects of this resonance.

With reference to FIG. 12, the frequency response C5 of the speaker 56 at 10 cm, facing the rear of the acoustic box, with a conventional cover, and the frequency response C6 with the shielding cover 50 were also measured.

It can be seen that the reduction in the volume of the cavity leads to an increase in the frequency of the resonance peak. Furthermore, the overall level of the curve C6 is higher, that shows that the amount of energy radiated from the rear is greater. Also, the frequency response measured with the shielding cover 50 is more homogeneous and flatter (e.g., +/−2 dB in the speaker bandwidth).

Naturally, the invention is not limited to the embodiments described, but comprises any variant entering into the scope of the invention such as defined by the claims.

The electrical equipment wherein the invention is implemented does not necessarily need to be a set-top box. The invention applies to any audio equipment (i.e., any equipment capable of reproducing a sound signal) comprising at least one speaker, electronic components and a shielding cover: a connected speaker, a television, etc.

The shielding device, comprising the shielding cover does not necessarily comprise a shielding belt. The shielding cover may be attached to the circuit board (and connected to the ground plane) in a different way.

The speaker does not necessarily need to be a woofer speaker.

The speaker diaphragm does not necessarily need to have a circular diaphragm, it may be square or rectangular in section.

1. An audio equipment comprising:
a printed circuit on which at least one electronic component is mounted;
a speaker comprising a diaphragm;
a shielding cover arranged to protect the at least one electronic component from electromagnetic disturbances, the shielding cover comprising an external face positioned facing the diaphragm of the speaker;
the external face comprising at least one curved surface that extends from a central portion of the external face towards a contour of the external face, the shielding cover thus being arranged to diffract acoustic waves produced by the diaphragm of the speaker in operation so as to reduce undesirable vibrations of the printed circuit and of the shielding cover.

2. The audio equipment according to claim 1, wherein a central axis (X1) of the shielding cover, passing through a centre of the external face, is combined with a central axis (X2) of the speaker.

3. The audio equipment according to claim 2, wherein a free space that extends between, on the one hand, the diaphragm and a core cover of the speaker, and, on the other hand, the shielding cover, has a h substantially constant height.

4. The audio equipment according to claim 3, wherein the diaphragm is a circular membrane and wherein the height h is such that:
$$h = D / 4 ,$$
where D is a diameter of the diaphragm.

5. The audio equipment according to claim 3, wherein the external face of the shielding cover comprises:
a frustoconical surface, comprising a concavity that extends inside of the frustoconical surface;
a bead that extends at least over a certain length of the contour of the external face;
and wherein the diaphragm of the speaker extends facing the frustoconical surface, a core cover of the speaker extends facing the concavity, and a suspension of the speaker extends at least partially in a channel defined between the bead and the frustoconical surface.

6. The audio equipment according to claim 5, wherein the bead extends over only a portion of the length of the contour of the external face, such that said channel comprises two ends and allows an air flow moved by the diaphragm of the speaker to flow via these two ends.

7. The audio equipment according to claim 5, wherein the external face of the shielding cover has, when viewed in cross-section along a plane passing through the central axis (X1) of the shielding cover, a parabolic shape at the bead.

8. The audio equipment according to claim 6, wherein the shielding cover comprises, in terms of at least one end of the channel, an extension that extends the bead and that at least partially covers another component mounted on the printed circuit.

9. The audio equipment according to claim 1, wherein the shielding cover is attached to a shielding belt mounted on the printed circuit and surrounding the at least one electronic component, the shielding cover having an internal face wherein an internal cavity is formed, the shielding cover extending on either side of the shielding belt that is positioned in the internal cavity.

10. The audio equipment according to claim 1, the audio equipment being a set-top box.

11. The audio equipment according to claim 7, wherein the shielding cover comprises, in terms of at least one end of the channel, an extension that extends the bead and that at least partially covers another component mounted on the printed circuit.
